(19) United States
(12) Patent Application Publication
(10) Pub. No.: US 2019/0018091 A1
(43) Pub. Date: Jan. 17, 2019

(54) MAGNETOMETER WITH THERMALLY COMPENSATED BIAS MAGNET

(71) Applicant: LOCKHEED MARTIN CORPORATION, Bethesda, MD (US)

(72) Inventors: Wilbur LEW, Bethesda, MD (US); Andrew MANDEVILLE, Bethesda, MD (US); Joseph W. HAHN, Bethesda, MD (US)

(73) Assignee: LOCKHEED MARTIN CORPORATION, Bethesda, MD (US)

(21) Appl. No.: 16/032,051

(22) Filed: Jul. 10, 2018

Related U.S. Application Data
(60) Provisional application No. 62/531,344, filed on Jul. 11, 2017.

(51) Int. Cl. G01R 33/383; G01R 33/26; G01R 33/32

(52) U.S. Cl. CPC G01R 33/383; G01R 33/323; G01R 33/26

(57) ABSTRACT

A magnetometer for magnetic detection includes a magneto-optical defect center material including at least one magneto-optical defect center that emits an optical signal when excited by an excitation light, a radio frequency (RF) exciter system configured to provide RF excitation to the magneto-optical defect center material, an optical excitation system configured to direct the excitation light to the magneto-optical defect center material, an optical detector configured to receive the optical signal emitted by the magneto-optical defect center material based on the excitation light and the RF excitation, and a magnetic field generator configured to generate a magnetic field detected at the magneto-optical defect center material, the magnetic field generator including a plurality of permanent magnets arranged in a Halbach array.

### CROSS-REFERENCE TO RELATED APPLICATIONS

This application claims the benefit of and priority to U.S. Provisional Application No. 62/531,344 filed on Jul. 11, 2017, the entire disclosure of which is incorporated by reference herein.

### FIELD

The present disclosure generally relates, in general, to magnetometers using magneto-optical defect center materials. More particularly, the present disclosure relates to a thermally compensated bias magnet within such a magnetometer.

### BACKGROUND

The following description is provided to assist the understanding of the reader. None of the information provided or references cited is admitted to be prior art. Some magnetometers use magneto-optical defect center materials to determine a magnetic field. Such magnetometers can direct light into the magneto-optical defect center material. Magneto-optical defect center materials with defect centers can be used to sense an applied magnetic field by transmitting light into the materials and measuring the responsive light that is emitted.

A number of industrial and scientific areas such as physics and chemistry can benefit from magnetic detection and imaging with a device that has improved sensitivity and/or the ability to capture signals that fluctuate rapidly (i.e., improved bandwidth) with a package that is small in size, efficient in power and reduced in volume.

### SUMMARY

According to some embodiments, a magnetometer for magnetic detection may include a magneto-optical defect center material including at least one magneto-optical defect center that emits an optical signal when excited by an excitation light, a radio frequency (RF) exciter system configured to provide RF excitation to the magneto-optical defect center material, an optical excitation system configured to direct the excitation light to the magneto-optical defect center material, an optical detector configured to receive the optical signal emitted by the magneto-optical defect center material based on the excitation light and the RF excitation, and a magnetic field generator configured to generate a magnetic field detected at the magneto-optical defect center material, the magnetic field generator including a plurality of permanent magnets arranged in a Halbach array.

According to some embodiments, a magnetic field generator may include a plurality of permanent magnets arranged in a Halbach array. A first subset of the plurality of permanent magnets is comprised of a first magnetic material. A second subset of the plurality of permanent magnets is comprised of a second magnetic material different from the first magnetic material.

According to some embodiments, a magnetometer for magnetic detection may include a magneto-optical defect center material comprising at least one magneto-optical defect center that emits an optical signal when excited by an excitation light; radio frequency (RF) excitation means for providing RF excitation to the magneto-optical defect center material; optical excitation means for directing the excitation light to the magneto-optical defect center material; optical detection means for detecting the optical signal emitted by the magneto-optical defect center material based on the excitation light and the RF excitation; and magnetic field generation means for generating a magnetic field detected at the magneto-optical defect center material, the magnetic field generation means including a plurality of permanent magnets arranged in a Halbach array.

The foregoing summary is illustrative only and is not intended to be in any way limiting. In addition to the illustrative aspects, embodiments, and features described above, further aspects, embodiments, and features will become apparent by reference to the following drawings and the detailed description.

### BRIEF DESCRIPTION OF THE DRAWINGS

FIG. 1 illustrates one orientation of a Nitrogen-Vacancy (NV) center in a diamond lattice.

FIG. 2 illustrates an energy level diagram showing energy levels of spin states for the NV center.

FIG. 3A is a schematic diagram illustrating a NV center magnetic sensor system.

FIG. 3B is a schematic diagram illustrating a NV center magnetic sensor system with a waveplate in accordance with some illustrative embodiments.

FIG. 4 is a graph illustrating the fluorescence as a function of an applied RF frequency of an NV center along a given direction for a zero magnetic field, and also for a non-zero magnetic field having a component along the NV axis.

FIG. 5A is a schematic illustrating a Ramsey sequence of optical excitation pulses and RF excitation pulses.

FIG. 5B is a graph illustrating the fluorescence as a function of an applied RF frequency for four different NV center orientations for a non-zero magnetic field.

FIG. 6A is a schematic diagram illustrating some embodiments of a magnetic field detection system.

FIG. 6B is another schematic diagram illustrating some embodiments of a magnetic field detection system.

FIG. 6C is another schematic diagram illustrating some embodiments of a magnetic field detection system.

FIG. 7 illustrates a magnetometer in accordance with some illustrative embodiments.

FIG. 8 illustrates some embodiments of a mounting frame of a magnetic field generator of the magnetometer of FIG. 7.

FIG. 9 illustrates some embodiments of the mounting frame of FIG. 8 and a magneto-optical defect center material mounted to a base with the magneto-optical defect center material provided at a center of the mounting frame.

FIG. 10 illustrates other embodiments of a mounting frame of a magnetic field generator of the magnetometer of FIG. 7.

FIG. 11 illustrates examples of a uniform magnetic field generated by the magnetic field generator of FIG. 10.

FIGS. 12A and 12B illustrate some different views of the mounting frame of FIG. 10 and a magneto-optical defect center material mounted to a base with the magneto-optical defect center material provided offset from a center of the mounting frame.

It will be recognized that some or all of the figures are schematic representations for purposes of illustration. The figures are provided for the purpose of illustrating one or more embodiments with the explicit understanding that they will not be used to limit the scope or the meaning of the claims.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure.

Atomic-sized magneto-optical defect centers, such as nitrogen-vacancy (NV) centers in diamond lattices, can have excellent sensitivity for magnetic field measurement and enable fabrication of small magnetic sensors. Magneto-optical defect center materials include but are not be limited to diamonds, Silicon Carbide (SiC), Phosphorous, and other materials with nitrogen, boron, carbon, silicon, or other defect centers. Diamond nitrogen vacancy (DNV) sensors may be maintained in room temperature and atmospheric pressure and can be even used in liquid environments. A green optical source (e.g., a micro-LED) can optically excite NV centers of the DNV sensor and cause emission of fluorescence radiation (e.g., red light) under off-resonant optical excitation. A magnetic field generated, for example, by a microwave coil can probe triplet spin states (e.g., with ms=−1, 0, +1) of the NV centers to split based upon an external magnetic field projected along the NV axis, resulting in two spin resonance frequencies. The distance between the two spin resonance frequencies is a measure of the strength of the external magnetic field. A photo detector can measure the fluorescence (red light) emitted by the optically excited NV centers.

Magneto-optical defect center materials are those that can modify an optical wavelength of light directed at the defect center based on a magnetic field in which the magneto-defect center material is exposed. In some implementations, the magneto-optical defect center material may utilize nitrogen vacancy centers. Nitrogen-vacancy (NV) centers are defects in a diamond's crystal structure. Synthetic diamonds can be created that have these NV centers. NV centers generate red light when excited by a light source, such as a green light source, and microwave radiation. When an excited NV center diamond is exposed to an external magnetic field, the frequency of the microwave radiation at which the diamond generates red light and the intensity of the generated red light change. By measuring this change and comparing the change to the microwave frequency that the diamond generates red light at when not in the presence of the external magnetic field, the external magnetic field strength can be determined. Accordingly, NV centers can be used as part of a magnetic field sensor.

In some implementations, microwave RF excitation may be used in a DNV sensor. The more uniform the microwave signal is across the NV centers in the diamond, the better and more accurate a NV sensor can perform. Uniformity, however, can be difficult to achieve. Also, the larger the bandwidth of the element, the better the NV sensor can perform. Large bandwidth, such as octave bandwidth, however, can be difficult to achieve. Various NV sensors respond to a microwave frequency that is not easily generated by RF antenna elements that are comparable to the small size of the NV sensor. In addition, RF elements reduce the amount of light within the sensor that is blocked by the RF elements. When a single RF element is used, the RF element is offset from the NV diamond when the RF element maximizes the faces and edges of the diamond that light can enter or leave. Moving the RF element away from the NV diamond, however, impacts the uniformity of strength of the RF that is applied to the NV diamond.

Some of the embodiments realize that the DNV magnetic sensors with dual RF elements provide a number of advantages. As described in greater detail below, using a two RF element arrangement in a DNV sensor can allow greater access to the edges and faces of the diamond for light input and egress, while still exciting the NV centers with a uniform RF field. In some implementations, each of the two microwave RF elements is contained on a circuit board. The RF elements can include multiple stacked spiral antenna coils. These stacked coils can occupy a small footprint and can provide the microwave RF field such that the RF field is uniform over the NV diamond.

In addition, all edges and faces of the diamond can be used for light input and egress. The more light captured by photo-sensing elements of a DNV senor can result in an increased efficiency of the sensor. Various implementations use the dual RF elements to increase the amount of light collected by the DNV sensor. The dual RF elements can be fed by a single RF feed or by two separate RF feeds. If there are two RF feeds, the feeds can be individual controlled creating a mini-phased array antenna effect, which can enhance the operation of the DNV sensor.

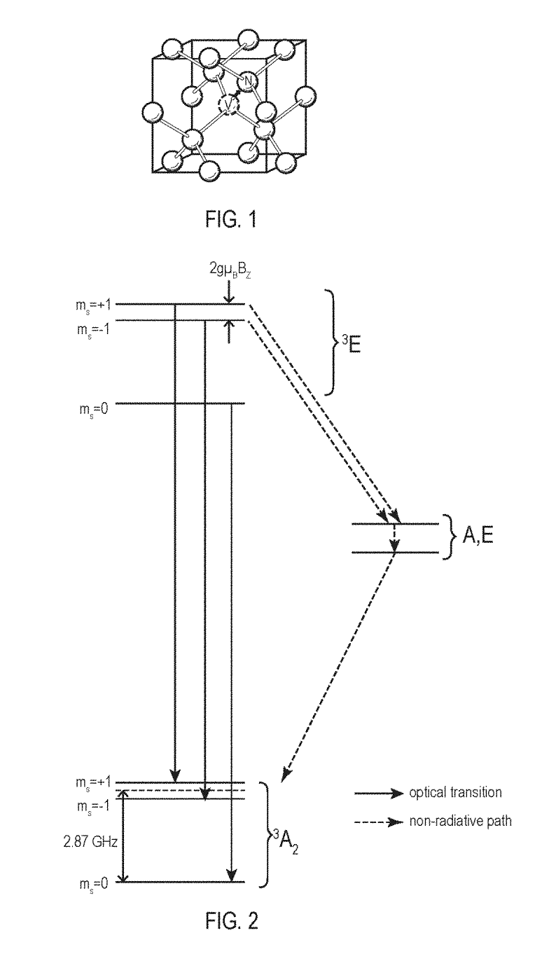

The NV center in a diamond may comprise a substitutional nitrogen atom in a lattice site adjacent a carbon vacancy as shown in FIG. 1. The NV center may have four orientations, each corresponding to a different crystallographic orientation of the diamond lattice.

The NV center may exist in a neutral charge state or a negative charge state. The neutral charge state uses the nomenclature NV°, while the negative charge state uses the nomenclature NV, which is adopted in this description.

The NV center has a number of electrons, including three unpaired electrons, each one from the vacancy to a respective of the three carbon atoms adjacent to the vacancy, and a pair of electrons between the nitrogen and the vacancy. The NV center, which is in the negatively charged state, also includes an extra electron.

The NV center has rotational symmetry, and as shown in FIG. 2, has a ground state, which is a spin triplet with ³A₂ symmetry with one spin state mₛ=0, and two further spin states mₛ=+1, and mₛ=−1. In the absence of an external magnetic field, the mₛ=±1 energy levels are offset from the mₛ=0 due to spin-spin interactions, and the mₛ=±1 energy levels are degenerate, i.e., they have the same energy. The mₛ=0 spin state energy level is split from the mₛ=±1 energy levels by an energy of approximately 2.87 GHz for a zero external magnetic field.

Introducing an external magnetic field with a component along the NV axis lifts the degeneracy of the mₛ=±1 energy levels, splitting the energy levels mₛ=±1 by an amount 2 gμ_{B}B_{z}, where g is the g-factor, μ_{B} is the Bohr magneton, and B_{z} is the component of the external magnetic field along the NV axis. This relationship is correct to a first order and inclusion of higher order corrections is a straightforward matter and will not affect the computational and logic steps in the systems and methods described below.

The NV center electronic structure further includes an excited triplet state ³E with corresponding mₛ=0 and mₛ=±1 spin states. The optical transitions between the ground state ³A₂ and the excited triplet ³E are predominantly spin conserving, meaning that the optical transitions are between initial and final states that have the same spin. For a direct transition between the excited triplet ³E and the ground state ³A₂, a photon of red light is emitted with a photon energy corresponding to the energy difference between the energy levels of the transitions.

There is, however, an alternative non-radiative decay route from the triplet ³E to the ground state ³A₂ via intermediate electron states, which are thought to be intermediate singlet states A, E with intermediate energy levels. Significantly, the transition rate from the mₛ=±1 spin states of the excited triplet ³E to the intermediate energy levels is significantly greater than the transition rate from the mₛ=0 spin state of the excited triplet ³E to the intermediate energy levels. The transition from the singlet states A, E to the ground state triplet ³A₂ predominantly decays to the mₛ=0 spin state over the mₛ=±1 spins states. These features of the decay from the excited triplet ³E state via the intermediate singlet states A, E to the ground state triplet ³A₂ allows that if optical excitation is provided to the system, the optical excitation will eventually pump the NV center into the mₛ=0 spin state of the ground state ³A₂. In this way, the population of the mₛ=0 spin state of the ground state ³A₂ may be “reset” to a maximum polarization determined by the decay rates from the triplet ³E to the intermediate singlet states.

Another feature of the decay is that the fluorescence intensity due to optically stimulating the excited triplet ³E state is less for the mₛ=±1 states than for the mₛ=0 spin state. This is so because the decay via the intermediate states does not result in a photon emitted in the fluorescence band, and because of the greater probability that the mₛ=±1 states of the excited triplet ³E state will decay via the non-radiative decay path. The lower fluorescence intensity for the mₛ=±1 states than for the mₛ=0 spin state allows the fluorescence intensity to be used to determine the spin state. As the population of the mₛ=±1 states increases relative to the mₛ=0 spin, the overall fluorescence intensity will be reduced.

### The NV Center, or Magneto-Optical Defect Center, Magnetic Sensor System

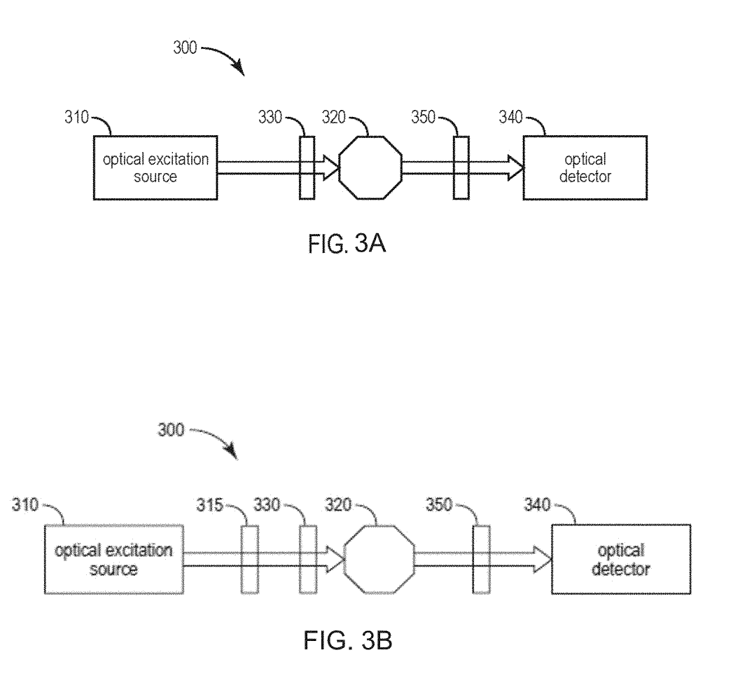

FIG. 3A is a schematic diagram illustrating a NV center magnetic sensor system 300A that uses fluorescence intensity to distinguish the mₛ=±1 states, and to measure the magnetic field based on the energy difference between the mₛ=+1 state and the mₛ=−1 state, as manifested by the RF frequencies corresponding to each state. The system 300A includes an optical excitation source 310, which directs optical excitation to an NV diamond material 320 with NV centers. The system further includes an RF excitation source 330, which provides RF radiation to the NV diamond material 320. Light from the NV diamond may be directed through an optical filter 350 to an optical detector 340.

The RF excitation source 330 may be a microwave coil, for example. The RF excitation source 330, when emitting RF radiation with a photon energy resonant with the transition energy between ground mₛ=0 spin state and the mₛ=+1 spin state, excites a transition between those spin states. For such a resonance, the spin state cycles between ground mₛ=0 spin state and the mₛ=+1 spin state, reducing the population in the mₛ=0 spin state and reducing the overall fluorescence at resonances. Similarly, resonance and a subsequent decrease in fluorescence intensity occurs between the mₛ=0 spin state and the mₛ=−1 spin state of the ground state when the photon energy of the RF radiation emitted by the RF excitation source is the difference in energies of the mₛ=0 spin state and the mₛ=−1 spin state.

The optical excitation source 310 may be a laser or a light emitting diode, for example, which emits light in the green (light having a wavelength such that the color is green), for example. The optical excitation source 310 induces fluorescence in the red, which corresponds to an electronic transition from the excited state to the ground state. Light from the NV diamond material 320 is directed through the optical filter 350 to filter out light in the excitation band (in the green, for example), and to pass light in the red fluorescence band, which in turn is detected by the optical detector 340. The optical excitation source 310, in addition to exciting fluorescence in the NV diamond material 320, also serves to reset the population of the mₛ=0 spin state of the ground state ³A₂ to a maximum polarization, or other desired polarization.

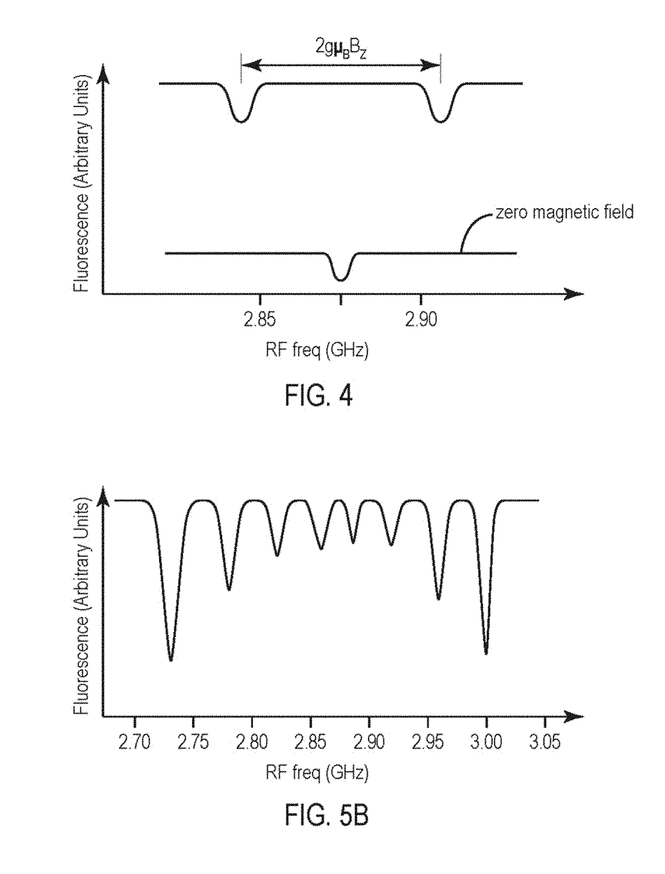

For continuous wave excitation, the optical excitation source 310 continuously pumps the NV centers, and the RF excitation source 330 sweeps across a frequency range that includes the zero splitting (when the mₛ=±1 spin states have the same energy) photon energy of approximately 2.87 GHz. The fluorescence for an RF sweep corresponding to a NV diamond material 320 with NV centers aligned along a single direction is shown in FIG. 4 for different magnetic field components B_{z} along the NV axis, where the energy splitting between the mₛ=−1 spin state and the mₛ=+1 spin state increases with B_{z}. Thus, the component B_{z} may be determined. Optical excitation schemes other than continuous wave excitation are contemplated, such as excitation schemes involving pulsed optical excitation, and pulsed RF excitation. Examples of pulsed excitation schemes include Ramsey pulse sequence, and spin echo pulse sequence.

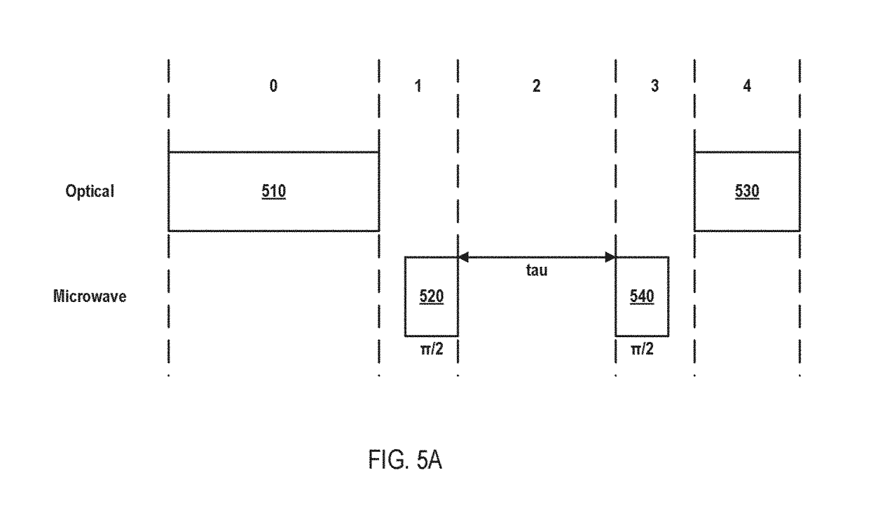

The Ramsey pulse sequence is a pulsed RF-pulsed laser scheme that measures the free precession of the magnetic moment in the NV diamond material 320 with NV centers, and is a technique that quantum mechanically prepares and samples the electron spin state. FIG. 5A is a schematic diagram illustrating the Ramsey pulse sequence. As shown in FIG. 5A, a Ramsey pulse sequence includes optical excitation pulses and RF excitation pulses over a five-step period. In a first step, during a period 0, a first optical excitation pulse 510 is applied to the system to optically pump electrons into the ground state (i.e., mₛ=0 spin state). This is followed by a first RF excitation pulse 520 (in the form of, for example, a microwave (MW) π/2 pulse) during a period 1. The first RF excitation pulse 520 sets the system into superposition of the mₛ=0 and mₛ=+1 spin states (or, alternatively, the mₛ=0 and mₛ=−1 spin states, depending on the choice of resonance location). During a period 2, the system is allowed to freely precess (and dephase) over a time period referred to as tau (τ). During this free precession time period, the system measures the local magnetic field and serves as a coherent integration. Next, a second RF excitation pulse 540 (in the form of, for example, a MWπ/2 pulse) is applied during a period 3 to project the system back to the mₛ=0 and mₛ=+1 basis. Finally, during a period 4, a second optical pulse 530 is applied to optically sample the system and a measurement basis is obtained by detecting the fluorescence intensity of the system. The RF excitation pulses applied are provided at a given RF frequency, which correspond to a given NV center orientation.

In general, the NV diamond material 320 will have NV centers aligned along directions of four different orientation classes. FIG. 5B illustrates fluorescence as a function of RF frequency for the case where the NV diamond material 320 has NV centers aligned along directions of four different orientation classes. In this case, the component B_{z} along each of the different orientations may be determined. These results, along with the known orientation of crystallographic planes of a diamond lattice, allow not only the magnitude of the external magnetic field to be determined, but also the direction of the magnetic field.

FIG. 3B is a schematic diagram illustrating a NV center magnetic sensor system 300B with a waveplate 315. The NV center magnetic sensor system 300B uses fluorescence intensity to distinguish the mₛ=+1 states, and to measure the magnetic field based on the energy difference between the mₛ=+1 state and the mₛ=−1 state. The system 300B includes an optical excitation source 310, which directs optical excitation through a waveplate 315 to a NV diamond material 320 with defect centers (e.g., NV diamond material). The system further includes an RF excitation source 330, which provides RF radiation to the NV diamond material 320. Light from the NV diamond may be directed through an optical filter 350 to an optical detector 340.

In some implementations, the RF excitation source 330 may be a microwave coil. The RF excitation source 330, when emitting RF radiation with a photon energy resonant with the transition energy between ground mₛ=0 spin state and the mₛ=+1 spin state, excites a transition between those spin states. For such a resonance, the spin state cycles between ground mₛ=0 spin state and the mₛ=+1 spin state, reducing the population in the mₛ=0 spin state and reducing the overall fluorescence at resonances. Similarly, resonance occurs between the mₛ=0 spin state and the mₛ=−1 spin state of the ground state when the photon energy of the RF radiation emitted by the RF excitation source is the difference in energies of the mₛ=0 spin state and the mₛ=−1 spin state, or between the mₛ=0 spin state and the mₛ=+1 spin state, there is a decrease in the fluorescence intensity.

In some implementations, the optical excitation source 310 may be a laser or a light emitting diode which emits light in the green. In some implementations, the optical excitation source 310 induces fluorescence in the red, which corresponds to an electronic transition from the excited state to the ground state. In some implementations, the light from the optical excitation source 310 may be directed through a waveplate 315. In some implementations, light from the NV diamond material 320 may be directed through the optical filter 350 to filter out light in the excitation band (in the green, for example), and to pass light in the red fluorescence band, which in turn may be detected by the optical detector 340. The optical excitation source 310, in addition to exciting fluorescence in the NV diamond material 320, also serves to reset the population of the mₛ=0 spin state of the ground state ³A₂ to a maximum polarization, or other desired polarization.

In some implementations, the light may be directed through a waveplate 315. In some implementations, the waveplate 315 may be in a shape analogous to a cylinder solid with an axis, height, and a base. In some implementations, the performance of the system may be affected by the polarization of the light (e.g., light from a laser) as it may be lined up with a crystal structure of the NV diamond material 320. In some implementations, a waveplate 315 may be mounted to allow for rotation of the waveplate 315 with the ability to stop and/or lock the waveplate 315 in to position at a specific rotation orientation. This allows the tuning of the polarization relative to the NV diamond material 320. Affecting the polarization of the system allows for the affecting the responsive Lorentzian curves. In some implementations where the waveplate 315 is a half-wave plate such that, when a laser polarization may be lined up with the orientation of a given lattice of the NV diamond material 320, the contrast of the dimming Lorentzian, the portion of the light sensitive to magnetic fields, is deepest and narrowest so that the slope of each side of the Lorentzian is steepest. In some implementations where the waveplate 315 is a half-wave plate, a laser polarization lined up with the orientation of a given lattice of the NV diamond material 320 allows extraction of maximum sensitivity for the measurement of an external magnetic field component aligned with the given lattice. In some implementations, four positions of the waveplate 315 are determined to maximize the sensitivity to different lattices of the NV diamond material 320. In some implementations, a position of the waveplate 315 may be determined to get similar sensitivities or contrasts to the four Lorentzians corresponding to lattices of the NV diamond material 320.

In some implementations where the waveplate 315 may be a half-wave plate, a position of the waveplate 315 may be determined as an initial calibration for a light directed through a waveplate 315. In some implementations, the performance of the system may be affected by the polarization of the light (e.g., light from a laser) as it may be lined up with a crystal structure of the NV diamond material 320. In some implementations, a waveplate 315 may be mounted to allow for rotation of the waveplate 315 with the ability to stop and/or lock the half-wave after an initial calibration determines the eight Lorentzians associated with a given lattice with each pair of Lorentzians associated with a given lattice plane symmetric around the carrier frequency. In some implementations, the initial calibration may be set to allow for high contrast with steep Lorentzians for a particular lattice plane. In some implementations, the initial calibration may be set to create similar contrast and steepness of the Lorentzians for each of the four lattice planes. The structural details of the waveplate 315 will be discussed in further detail below

While FIGS. 3A-3B illustrate an NV center magnetic sensor system 300A, 300B with NV diamond material 320 with a plurality of NV centers, in general, the magnetic sensor system may instead employ a different magneto-optical defect center material, with a plurality of magneto-optical defect centers. The electronic spin state energies of the magneto-optical defect centers shift with magnetic field, and the optical response, such as fluorescence, for the different spin states may be not the same for all of the different spin states. In this way, the magnetic field may be determined based on optical excitation, and possibly RF excitation, in a corresponding way to that described above with NV diamond material. Magneto-optical defect center materials include but are not limited to diamonds, Silicon Carbide (SiC) and other materials with nitrogen, boron, or other chemical defect centers. Our references to diamond-nitrogen vacancies and diamonds are applicable to magneto-optical defect center materials and variations thereof.

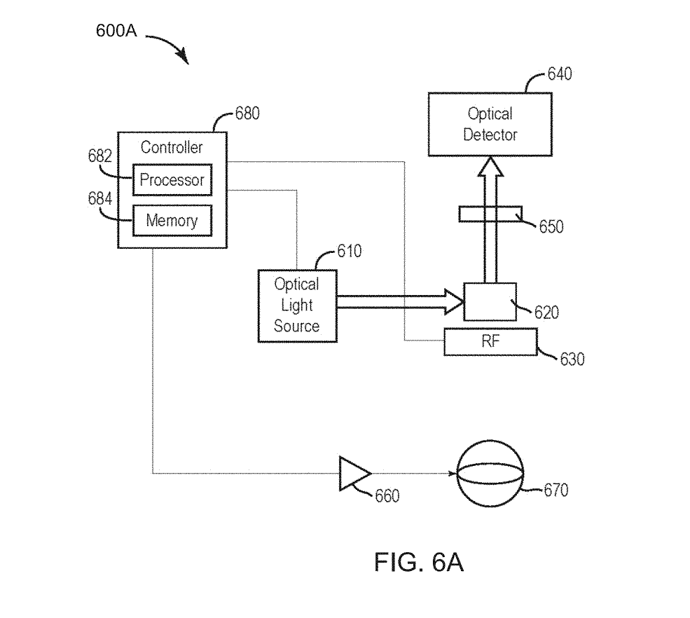

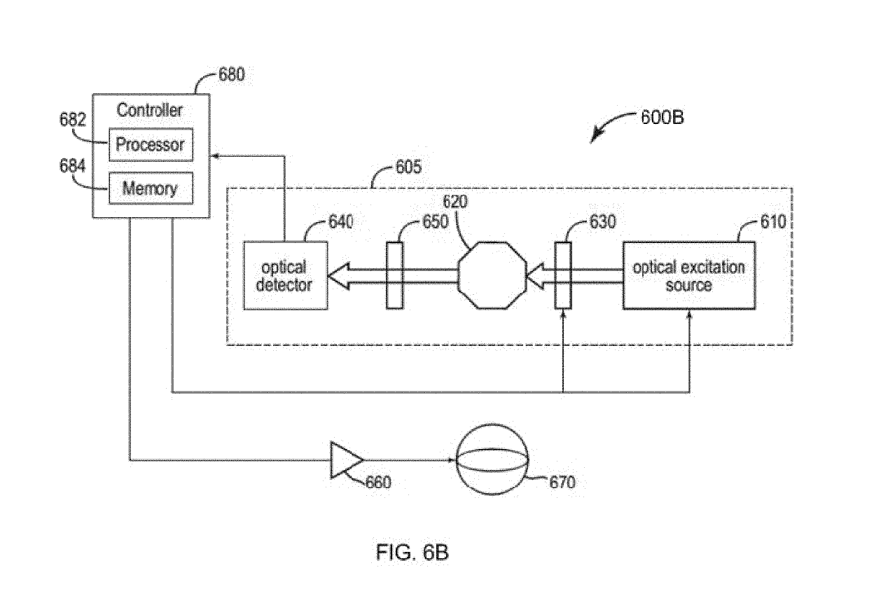

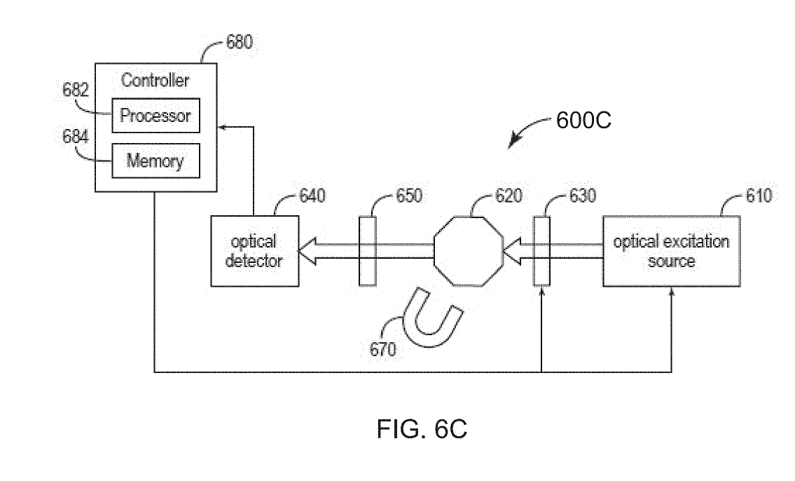

FIG. 6A illustrates a magnetic field detection system 600A according to some embodiments. The system 600A includes an optical light source 610 (i.e., the optical light source 310 of FIGS. 3A and 3B), which directs optical light to an NV diamond material 620 (i.e., the NV diamond material 320 of FIGS. 3A and 3B) with NV centers, or another magneto-optical defect center material with magneto-optical defect centers. An RF excitation source 630 (i.e., the RF excitation source 330 of FIGS. 3A and 3B) provides RF radiation to the NV diamond material 620. The system 600A may include a magnetic field generator 670 which generates a magnetic field, which may be detected at the NV diamond material 620, or the magnetic field generator 670 may be external to the system 600A. The magnetic field generator 670 may provide a biasing magnetic field.

FIG. 6B is another schematic diagram of a magnetic field detection system 600B according to some embodiments. The system 600B includes an optical excitation source 610 (i.e., the optical excitation source 310 of FIGS. 3A and 3B), which directs optical excitation to a NV diamond material 620 (i.e., the NV diamond material 320 of FIGS. 3A and 3B) with defect centers. An RF excitation source 630 (i.e., the RF excitation source 330 of FIGS. 3A and 3B) provides RF radiation to the NV diamond material 620. A magnetic field generator 670 generates a magnetic field, which may be detected at the NV diamond material 620.

Referring to both FIGS. 6A and 6B, the system 600A, 600B further includes a controller 680 arranged to receive a light detection signal from the optical detector 640 (i.e., the optical detector 340 of FIGS. 3A and 3B) and to control the optical light source 610, the RF excitation source 630, and the magnetic field generator 670. The controller 680 may be a single controller, or multiple controllers. For a controller 680 including multiple controllers, each of the controllers may perform different functions, such as controlling different components of the system 600A, 600B. The magnetic field generator 670 may be controlled by the controller 680 via an amplifier 660, for example.

The RF excitation source 630 may be controlled to emit RF radiation with a photon energy resonant with the transition energy between the ground mₛ=0 spin state and the mₛ=±1 spin states as discussed above with respect to FIGS. 3A or 3B, or to emit RF radiation at other no resonant photon energies.

The controller 680 may be arranged to receive a light detection signal from the optical detector 640 and to control the optical light source 610, the RF excitation source 630, and the magnetic field generator 670. The controller 680 may include a processor 682 and a memory 684, in order to control the operation of the optical light source 610, the RF excitation source 630, and the magnetic field generator 670. The memory 684, which may include a no transitory computer readable medium, may store instructions to allow the operation of the optical light source 610, the RF excitation source 630, and the magnetic field generator 670 to be controlled. That is, the controller 680 may be programmed to provide control.

The magnetic field generator 670 may generate magnetic fields with orthogonal polarizations, for example. In this regard, the magnetic field generator 670 may include two or more magnetic field generators, such as two or more Helmholtz coils. The two or more magnetic field generators may be configured to provide a magnetic field having a predetermined direction, each of which provide a relatively uniform magnetic field at the NV diamond material 620. The predetermined directions may be orthogonal to one another. In addition, the two or more magnetic field generators of the magnetic field generator 670 may be disposed at the same position, or may be separated from each other. In the case that the two or more magnetic field generators are separated from each other, the two or more magnetic field generators may be arranged in an array, such as a one-dimensional or two-dimensional array, for example.

The system 600A may be arranged to include one or more optical detection systems 605, where each of the optical detection systems 605 includes the optical detector 640, optical excitation source 610, and NV diamond material 620. Similarly, the system 600B also includes the optical detector 640, optical excitation source 610, and NV diamond material 620. The magnetic field generator 670 may have a relatively high power as compared to the optical detection systems 605. In this way, the optical systems 605 may be deployed in an environment that requires a relatively lower power for the optical systems 605, while the magnetic field generator 670 may be deployed in an environment that has a relatively high power available for the magnetic field generator 670 so as to apply a relatively strong magnetic field.

The RF excitation source 630 may be a microwave coil, for example behind the light of the optical excitation source 610. The RF excitation source 630 may be controlled to emit RF radiation with a photon energy resonant with the transition energy between the ground mₛ=0 spin state and the mₛ=±1 spin states as discussed above with respect to FIGS. 3A and 3B.

The optical excitation source 610 may be a laser or a light emitting diode, for example, which emits light in the green, for example. The optical excitation source 610 induces fluorescence in the red from the NV diamond material 620, where the fluorescence corresponds to an electronic transition from the excited state to the ground state. Light from the NV diamond material 620 may be directed through the optical filter 650 to filter out light in the excitation band (in the green, for example), and to pass light in the red fluorescence band, which in turn may be detected by the optical detector 640. The optical excitation light source 610, in addition to exciting fluorescence in the NV diamond material 620, also serves to reset the population of the mₛ=0 spin state of the ground state ³A₂ to a maximum polarization, or other desired polarization.

The controller 680 may be arranged to receive a light detection signal from the optical detector 640 and to control the optical excitation source 610, the RF excitation source 630, and a second magnetic field generator (not illustrated). The controller may include a processor 682 and a memory 684, in order to control the operation of the optical excitation source 610, the RF excitation source 630, and the second magnetic field generator. The memory 684, which may include a no transitory computer readable medium, may store instructions to allow the operation of the optical excitation source 610, the RF excitation source 630, and the second magnetic field generator to be controlled. That is, the controller 680 may be programmed to provide control.

FIG. 6C is a schematic of an NV center magnetic sensor system 600C, according to an embodiment. The sensor system 600C includes an optical excitation source 610, which directs optical excitation to an NV diamond material 620 with NV centers, or another magneto-optical defect center material with magneto-optical defect centers. An RF excitation source 630 provides RF radiation to the NV diamond material 620. The NV center magnetic sensor system 600C may include a bias magnet (bias magnetic field generator 670) applying a bias magnetic field to the NV diamond material 620. Unlike FIGS. 6A and 6B, the sensor system 600C of FIG. 6C does not include the amplifier 660. However, in some implementations of the NV center magnetic sensor system 600C, an amplifier 660 may be utilized. Light from the NV diamond material 620 may be directed through an optical filter 650 and optionally, an electromagnetic interference (EMI) filter (not illustrated), which suppresses conducted interference, to an optical detector 640. The sensor system 600C further includes a controller 680 arranged to receive a light detection signal from the optical detector 640 and to control the optical excitation source 610 and the RF excitation source 630.

The optical excitation source 610 may be a laser or a light emitting diode, for example, which emits light in the green, for example. The optical excitation source 610 induces fluorescence in the red, which corresponds to an electronic transition from the excited state to the ground state. Light from the NV diamond material 620 may be directed through the optical filter 650 to filter out light in the excitation band (in the green for example), and to pass light in the red fluorescence band, which in turn may be detected by the optical detector 640. In implementations including the EMI filter, the EMI filter may be arranged between the optical filter 650 and the optical detector 640 and suppresses conducted interference. The optical excitation light source 610, in addition to exciting fluorescence in the NV diamond material 620, also serves to reset the population of the mₛ=0 spin state of the ground state ³A₂ to a maximum polarization, or other desired polarization.

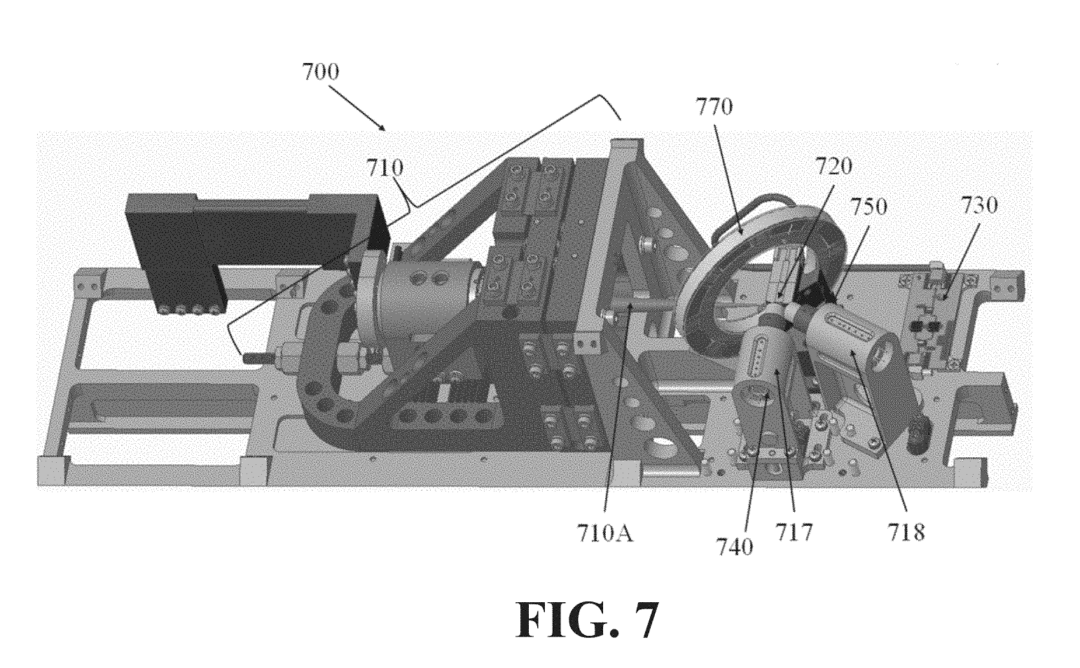

Referring to FIG. 7, a magnetometer 700 includes a magneto-optical defect center material 720 comprising at least one magneto-optical defect center that emits an optical signal when excited by an excitation light 710A, a radio frequency (RF) exciter system configured to provide RF excitation to the magneto-optical defect center material 720, an optical light system 710 configured to direct the excitation light 710A to a magneto-optical defect center material 720 (e.g., a nitrogen vacancy (NV) diamond material with one or more NV centers, or another magneto-optical defect center material with one or more magneto-optical defect centers), a magnetic field generator 770, and an optical detector 740 configured to receive the optical signal emitted by the magneto-optical defect center material based on the excitation light and the RF excitation. The RF exciter system may include may include an RF amplifier assembly 730, which includes RF circuitry that amplifies the signal from the RF source to a desired power level needed in the RF excitation element. In alternative embodiments, additional, fewer, and/or different elements may be used. For example, although the optical light system 710 of FIG. 7 illustrates one light source, in other embodiments, the optical light system 710 may include any suitable number of light sources, such as two, three, four, etc. light sources. An orientation of the magneto-optical defect center material 720 may be changed.

In the magnetometer 700, light from the magneto-optical defect center material 720 may be directed through an optical filter to filter out light in the excitation band (in the green, for example), and to pass light in the red fluorescence band through a light pipe, which in turn may be detected by the optical detector 740. A red collection 717 and a green collection 718 may be provided around a periphery of a base 750 to which the magneto-optical defect center material 720 and the magnetic field generator 770 are mounted. The red collection 717 may be a system of parts that includes, for example, a photo diode, a light pipe, and filters that measure the red light emitted from the magneto-optical defect center material 720. The red collection 717 provides the main signal of interest, used to measure external magnetic fields. The green collection 718 may be a system of parts that includes, for example, a photo diode, a light pipe, and filters that measure the green light from the excitation light that passes through the magneto-optical defect center material 720. The green collection 718 may be used in tandem with the red collection 717 to remove common mode noise in the detection signal, and therefore, increase device sensitivity. A beam trap configured to capture any portion of the excitation light (e.g., a green light portion) that may be not absorbed by the magneto-optical defect center material 720 may be provided to ensure that that the excitation light does not bounce around and add noise to the measurement. This noise could result from the excitation light bouncing off other components of the magnetometer 700 and hitting the magneto-optical defect center material 720 at a later time, where the excitation light would be absorbed and contaminate the signal. The excitation light that is not absorbed by the magneto-optical defect center material 720 might also be captured on the green or red collection photodiodes, directly adding noise to those signals.

### Magnetic Field Generator

As described above, in an optical defect center based magnetometer (e.g., the magnetometer 700 of FIG. 7), a bias magnetic field may be used. However, if the magnetometer is used in environments that have a large temperature range, the bias magnetic field needs to be very stable over the operational temperature because the performance of the magnetometer may be directly related to the magnetic field strength. A stable operational temperature may be a predetermined temperature plus or minus a few degrees Celsius, preferably, plus or minus tenths of a degree Celsius, and even more preferably, plus or minus hundredths of a degree Celsius. Active cooling methods may be used to maintain the bias magnet and/or the entire magnetometer at the stable operational temperature. However, active cooling systems capable of maintaining the stable operational temperature are large in size, high in power consumption, heavy, control software and hardware intensive, and expensive.

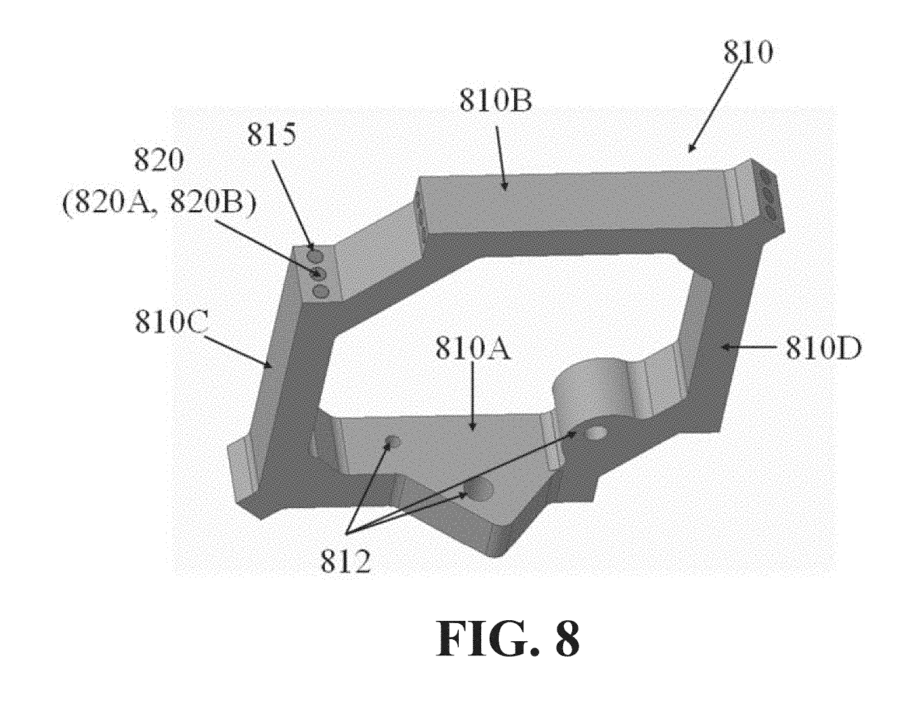

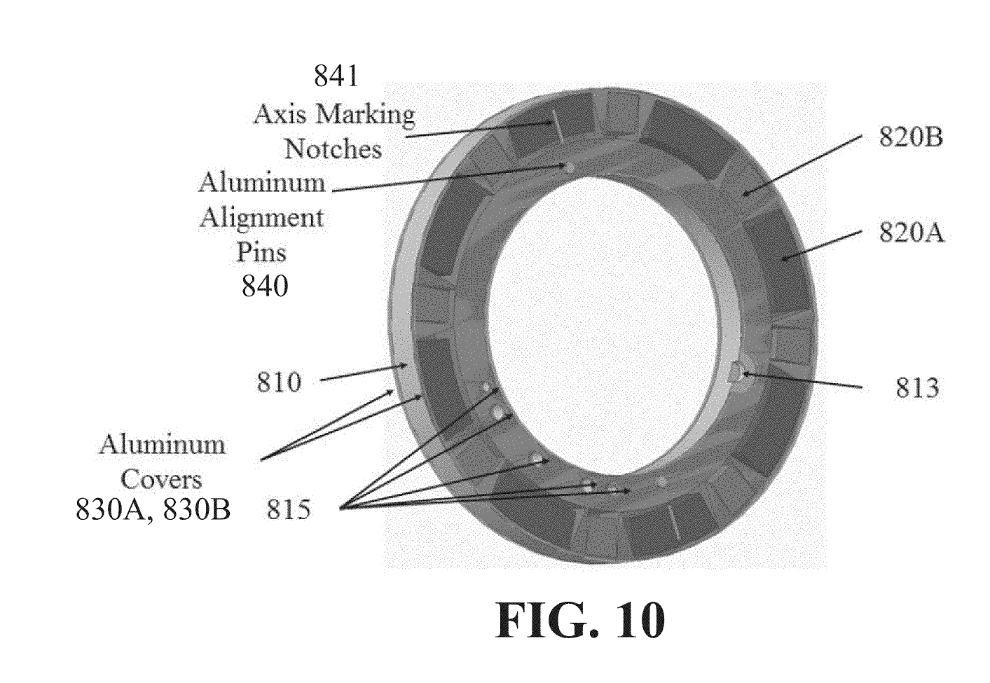

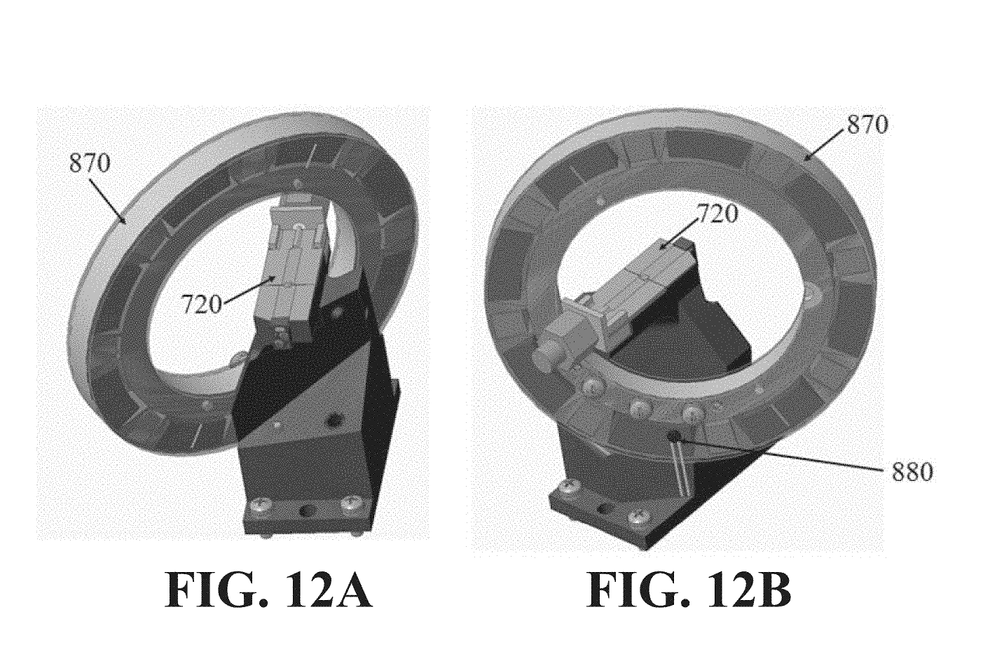

Referring to the embodiments illustrated in FIGS. 8-12B, a magnetometer (e.g., the magnetometer 700 of FIG. 7) includes a magnetic field generator 870 (e.g., the magnetic field generator 670 of FIGS. 6A-6C or the magnetic field generator 770 of FIG. 7). The magnetic field generator 870 includes a mounting frame 810 configured to support a plurality of permanent magnets 820. The mounting frame 810 may be made of plastic (e.g., Black Noryl® PPO™, polystyrene, polyphenylene ether, etc.), titanium (e.g., Grade 5, Ti6Al-4V, etc.), aluminum (e.g., 6061-T6 per ASTM B209, may have a chemical conversion coating per military standard MIL-DTL-5541, etc.), etc. The mounting frame 810 may be repeatedly and reversibly mounted to the base 750 to which the magneto-optical defect center material 720 may be also mounted. The mounting frame 810 may be mounted to the base 750 via one or more fasteners 811, each configured to be received in one of a plurality of alignment and mounting holes 812 provided in the mounting frame 810. The fasteners 811 can be any suitable device such as screws, bolts, studs, nuts, clips, etc. As seen in FIG. 10, the mounting frame 810 may include one or more cutouts 813 along an interior periphery thereof. The cutouts 813 are configured to prevent the permanent magnets 820 from blocking the excitation light 710A generated by the optical light system 710. A thermistor 880 may be epoxied (or otherwise attached) to one or more permanent magnets 820 to monitor a temperature thereof.

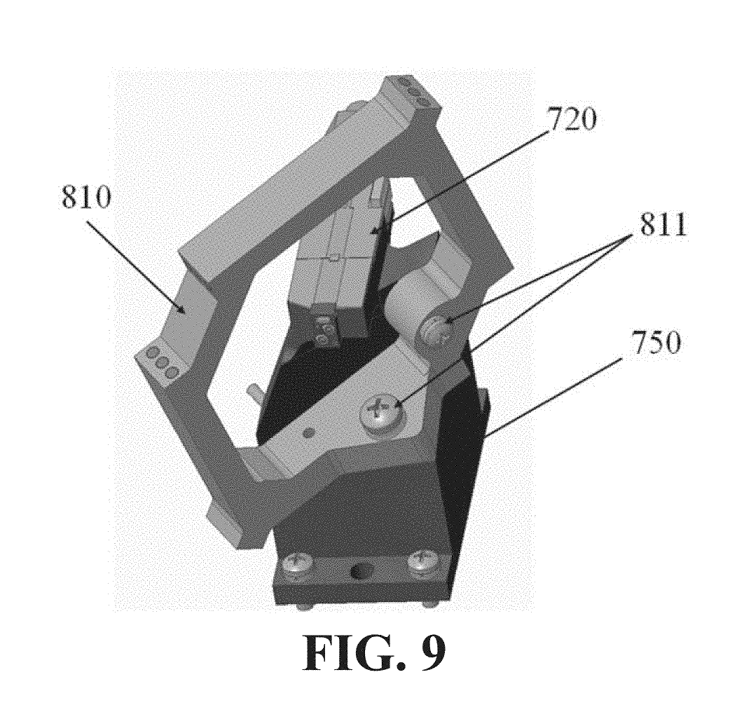

In the embodiment of FIGS. 8 and 9, the mounting frame 810 includes a lower portion 810A configured to be attached to the base 750, an upper portion 810B, and side portions 810C and 810D, which connect the lower portion 810A and the upper portion 810B. Portions that are not configured to receive a permanent magnet may be provided between the lower portion 810A and at least one of the side portions 810C and 810D, and/or between the upper portion 810B and at least one of the side portions 810C and 810D for structural integrity of the mounting frame 810 (i.e., to assist in holding the assembly together). Each of the upper portion 810B and the side portions 810C and 810D include a plurality of magnet mounting holes 815 in an interior thereof. The magnet mounting holes 815 extend along a length of each of the upper portion 810B and the side portions 810C and 810D. In this embodiment, the permanent magnets 820 are cylindrical magnets configured to be received in the magnet mounting holes 815. The permanent magnets 820 may be provided in specified positions along the mounting frame 810 to provide maximum uniformity of the generated magnetic field. Although there are three magnet mounting holes illustrated in each of the upper portion 810B and the side portions 810C and 810D, any suitable number of magnet mounting holes 815 may be provided such as two, four, five, six, etc. provided that the number of magnets is balanced and capable of providing magnetic field uniformity. In some examples, all of the magnet mounting holes 815 may receive at least one permanent magnet 820. In other examples, at least one of the magnet mounting holes 815 may be empty (i.e., not contain a permanent magnet 820) during operation of the magnetometer to adjust a strength of the magnet. In some examples, a same number of magnet mounting holes 815 on each of the upper portion 810B and the side portions 810C and 810D may contain a permanent magnet. One or more permanent magnets 820 having the same or different lengths can be received in each of the magnet mounting holes 815, where a plurality of permanent magnets 820 may be stacked in any given magnet mounting hole to change a strength of a magnetic field that may be generated. For example, some of the permanent magnets 820 may be 0.250 inches long with a 1/16 inch outer diameter, while other permanent magnets 820 may be 0.125 inches long with a 1/16 inch outer diameter. An individual magnet mounting hole 815 may be configured to hold two permanent magnets 820, for example, one of each size or two of the same size. Thus, the mounting frame 810 of FIGS. 8 and 9 can be adapted for use in a plurality of magnetometers.

In the embodiment of FIGS. 10-12B, the mounting frame 810 may be circular and has a plurality of recesses 825 in a front side thereof arranged along a circumference thereof. Each of the recesses 825 may be sized and shaped to receive an arcuate permanent magnet 820. The sizes of the recesses 825 may be uniform (i.e., all of the permanent magnets 820 have the same size and shape) or non-uniform (i.e., at least one of the permanent magnets 820 has a different size and/or shape than another permanent magnet 820). Because the mounting frame 810 may be fabricated to include recesses corresponding to a particular arrangement of permanent magnets, the mounting frame 810 of FIGS. 10-12B may be a customized magnet frame configured for use in a particular magnetometer. The magnetic field generator of FIGS. 10-12B may be held together with structural epoxy. A first cover 830A and a second cover 830B may be provided on opposite sides of the mounting frame 810. Mutual attraction or repulsion between the permanent magnets 820 may occur. The first cover 830A and the second cover 830B are configured to provide a clamping force to help hold the permanent magnets 820 in place. One or more alignment pins 840 and one or more axis markers 841 may be provided along the mounting frame 810 to facilitate proper orientation of the magnetic field vector in the assembly. The first cover 830a, the second cover 830B and/or the alignment pins 840 may be made, for example, of aluminum.

The permanent magnets 820 of FIGS. 8-12B are arranged in a Halbach array. One of ordinary skill in the art would understand that a Halbach array may be an arrangement of permanent magnets in which magnetic materials, for example, ferromagnetic materials, with alternating magnetizations are combined such that the magnetic fields align on one side of the Halbach array (e.g., above the plane of the magnetic materials), while the magnetic fields on the other side of the Halbach array (e.g., below the plane of the magnetic materials) are in opposite directions and cancel out in an ideal case. Because the ideal case may be never observed, a very small magnetic field may be produced on the other side of the Halbach array (e.g., below the plane of the magnetic materials).

The permanent magnets 820 of FIGS. 8-12B are comprised of one or more magnetic materials. In some embodiments, the permanent magnets 820 are comprised of two magnetic materials (i.e., a first magnetic material 820A and a second magnetic material 820B) such that the Halbach array may be a thermal compensated Halbach array configured to supply a stable bias magnetic field over large temperature ranges. As used herein, stable means that the magnetic field does not vary significantly over the timescale of a measurement. The primary driver for temporal changes in the magnetic field may be the change in the magnet's temperature. The metric of stability may either be the change in the field with respect to time [Tesla/s] or temperature [Tesla/K]. The latter may be more preferable in this context because the exact change in temperature vs. time may be a function of the magnetometer system. In some examples, a first subset of the plurality of permanent magnets 820 may be comprised of a first magnetic material 820A and a second subset of the plurality of permanent magnets 820 may be comprised of a second magnetic material 820B different from the first magnetic material 820A. The first magnetic material 820A and the second magnetic material 820B are selected such that the magnetic materials have different temperature coefficients, and thus, have a different slope when plotting a change of magnetic field versus temperature. The first magnetic material 820A and the second magnetic material 820B are arranged such that a temperature coefficient of the magnetic materials are cancelled, and the magnetic fields generated by the magnetic field generator 870 are essentially independent with respect to the operational temperature of the magnetometer. The cancellation may be achieved, for example, by aligning the magnetic fields generated by each of the first magnetic material 820A and the second magnetic material 820B in the opposite direction. In some examples, the first magnetic material 820A generates a weaker magnetic field, but has a smaller slope when plotting the change of magnetic field versus temperature as compared to the magnetic field and slope of the second magnetic material 820B. The first magnetic material 820A may be oriented to produce a magnetic field in a desired direction (e.g., above the plane of the magnetic materials), while the second magnetic material 820B may be oriented to produce a magnetic field in a direction opposite to the desired direction (e.g., below the plane of the magnetic materials).

The magnetic field, B, produced by a permanent magnet with a temperature coefficient, c, varies a function of temperature follows:

B(Tₒ+ΔT)=B(Tₒ)[1−cΔT] (1)

where Tₒ is the initial temperature and ΔT is the change in temperature. In our configuration we have two opposing magnets with different coefficients c₁ and c₂. The total temperature dependent field produced by this configuration is:

Bₜₒₜₐₗ(Tₒ+ΔT)=B₁(Tₒ)[1 c₁ΔT]−B₂(Tₒ)[1−c₂66 T] (2)

### At T=Tₒ:

Bₜₒₜₐₗ(Tₒ)=Bₒ=B₁(Tₒ)−B₂(Tₒ) (3)

To design a thermally stable magnet, set Bₜₒₜₐₗ(Tₒ+ΔT)=Bₒ, where Bₒ is the desired field and a constant with respect to temperature. Substituting Bₒ+B₂(Tₒ) for B₁ (Tₒ) in (2) and solving for B₂(Tₒ) gives:

$${B}_{2} ( {T}_{o} ) = \frac{{c}_{1}}{{c}_{2} - {c}_{1}} {B}_{o} \qquad ( 4 )$$

Using equations (3) and (4), the values of B₁(Tₒ) and B₂(Tₒ) can be designed to produce a thermally stable field of Bₒ.

From equation (4) if c₂˜c₁ then B₂ will be very large with respect to B₁ or if c₁<<c₂ then B₂ will be very small with respect to B₁, neither of which may be ideal. The first magnetic material 820A may be comprised, for example, of Samarium Cobalt (e.g., SmCo30) and the second magnetic material 820B may be comprised, for example, of Neodymium (e.g., N52). The difference between SmCo and N52 may be in a range where reasonable values of B₁ and B₂ can be achieved. Other ferromagnetic materials such as alnico alloys (composed primary of aluminum, nickel and cobalt) may be used as the first magnetic material 820A or the second magnetic material 820B. Alternatively, the first magnetic material 820A or the second magnetic material 820B may be comprised of ferrous iron. Another factor to consider in selecting the magnetic materials may be whether the permanent magnets 820 are strong enough to fit within the small footprint desired. This may substantially limit the choice of magnetic materials. A further consideration may be that the maximum operating temperature must be significantly smaller than the Curie temperature such that the magnetic field strength changes linearly with temperature, although this may be less of a concern because Curie temperatures are typically quite high.

In the embodiment of FIGS. 8 and 9, the permanent magnets 820 comprised of the first magnetic material 820A and the second magnetic material 820B may be provided in adjacent magnet mounting holes 815. Using the example of three magnet mounting holes 815 as illustrated in FIGS. 8 and 9, a first magnet mounting hole and a third magnet mounting hole may include permanent magnets 820 comprised of the first magnetic material 820A, while the second magnet mounting hole (i.e., the middle magnet mounting hole) includes permanent magnets 820 comprised of the second magnetic material 820B. Alternatively, the first magnet mounting hole and the third magnet mounting hole may include permanent magnets 820 comprised of the second magnetic material 820B, while the second magnet mounting hole (i.e., the middle magnet mounting hole) includes permanent magnets 820 comprised of the first magnetic material 820A. Alternatively, two adjacent magnet mounting holes (i.e., the first and the second, or second and third) may include permanent magnets 820 comprised of the first magnetic material 820A, while the remaining magnet mounting hole includes permanent magnets 820 comprised of the second magnetic material 820B. Alternatively, two adjacent magnet mounting holes (i.e., the first and the second, or second and third) may include permanent magnets 820 comprised of the second magnetic material 820B, while the remaining magnet mounting hole includes permanent magnets 820 comprised of the first magnetic material 820A.

As illustrated in 10-12B, the permanent magnets 820 comprised of the first magnetic material 820A and the second magnetic material 820B may be provided in an alternating fashion along a circumference of the mounting frame 810. For example, one permanent magnet 820 comprised of the first magnetic material 820A may be provided between two permanent magnets 820 comprised of the second magnetic material 820B, or one permanent magnet 820 comprised of the second magnetic material 820B may be provided between two permanent magnets 820 comprised of the first magnetic material 820A. Alternatively, one permanent magnet 820 comprised of the first magnetic material 820A may be provided between two permanent magnets comprised of the first magnetic material 820A or provided between one permanent magnet comprised of the first magnetic material 820A and one permanent magnet comprised of the second magnetic material 820B. Alternatively, one permanent magnet 820 comprised of the second magnetic material 820B may be provided between two permanent magnets comprised of the second magnetic material 820B or provided between one permanent magnet comprised of the first magnetic material 820A and one permanent magnet comprised of the second magnetic material 820B.

The sizes of the permanent magnets 820 in any of FIGS. 8-12B may be uniform or non-uniform. For example, when the sizes of the permanent magnets 820 are non-uniform, the permanent magnets 820 comprised of the first magnetic material 820A may be larger than the permanent magnets 820 comprised of the second magnetic material 820B. Alternatively, the permanent magnets 820 comprised of the first magnetic material 820A may be smaller than the permanent magnets 820 comprised of the second magnetic material 820B.

A number of permanent magnets 820 comprised of the first magnetic material and a number of permanent magnets 820 comprised of the second magnetic material may be the same or different in any of FIGS. 8-12B. For example, a number of permanent magnets 820 comprised of the first magnetic material may be greater than a number of permanent magnets 820 comprised of the second magnetic material. Alternatively, the number of permanent magnets 820 comprised of the first magnetic material may be less than a number of permanent magnets 820 comprised of the second magnetic material.

As noted above with respect to FIGS. 4 and 5, each of the dips (e.g., Lorentzians) in the graphs may correspond to one or more axes of the defect centers within the NV diamond material 620. The bias magnetic field applied to the magneto-optical defect center material 720 may adjust the order and orientation of the Lorentzian dips in the graphs. Accordingly, there are forty-eight unique orientations of the Lorentzians such that each Lorentzian is distinguishable from the others (e.g., as in the graph of FIG. 5). Thus, there are forty-eight unique positions of the permanent magnets 820 around the magneto-optical defect center material 720 corresponding to each of the forty-eight orientations of the Lorentzians.

In some illustrative embodiments, the mounting frame 810 may be movable such that twelve of the forty-eight positions of the magnets permanent magnets 820 are accessible. That is, the mounting frame 810 cannot be positioned into all of the forty-eight positions because the mounting frame 810 would interfere with the housing of the magnetometer, which may span across the top and bottom of the mounting frame 810. In some illustrative embodiments, the mounting frame 810 may be positioned such that the Lorentzians are distinguishable from one another and such that the light is not interfered with as it passes through the through-hole to the magneto-optical defect center material 720.

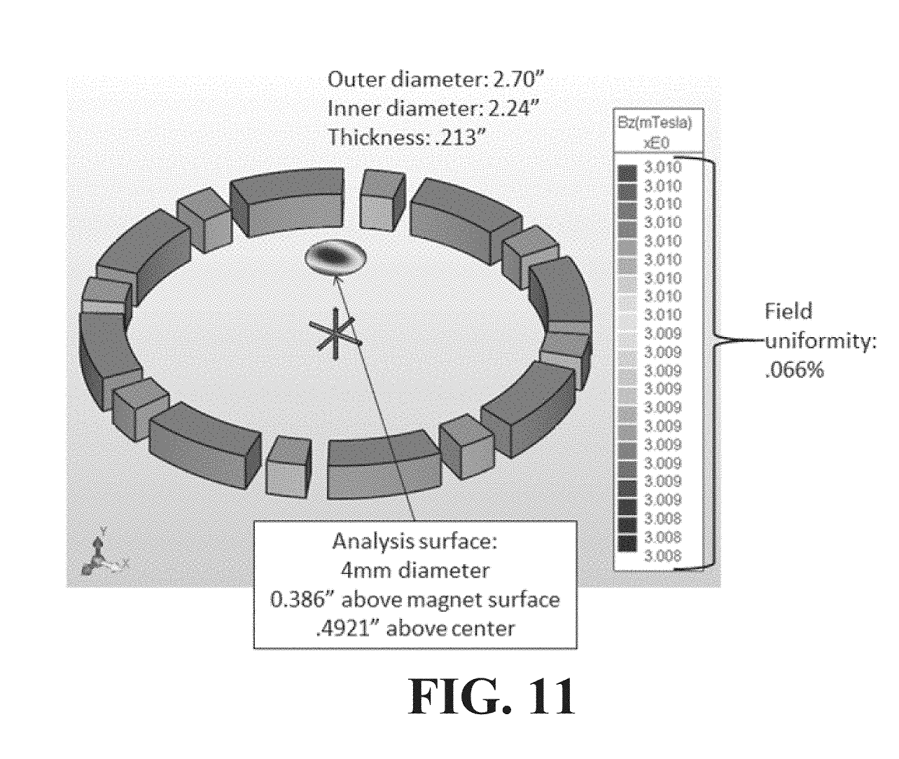

In some examples (see FIGS. 8-12B), the mounting frame 810 may be positioned such that the array of permanent magnets 820 are offset behind the magneto-optical defect center material 720. This creates a region having excellent magnetic field uniformity (see FIG. 11) in a plane of the magnetic field generator 870 that is centered on the magneto-optical defect center material 720. The dimensions included in FIG. 11 are non-limiting examples. Although this region provides excellent magnetic field uniformity in the x and y directions, the magnetic field may not be as uniform in the z direction. Therefore, in other examples (see FIGS. 8 and 9), the mounting frame 810 may be positioned such that the array of permanent magnets 820 are not offset with respect to the magneto-optical defect center material 720. This orientation results in slightly less magnetic field uniformity in the x and y directions, but greater magnetic field uniformity in the z direction.

By providing a magnetic field generator 870 including the thermal compensated Halbach magnet arrays described above, it may be possible to supply a very stable bias magnetic field over large temperature ranges. In particular, use of the thermal compensated Halbach magnet arrays removes the need to control the magnet temperature to the levels required by a non-thermal-compensated magnet. For example, instead of requiring maintenance of a temperature in a range of the predetermined temperature plus or minus tenths of a degree Celsius over the full test time (e.g., on the order of several hours), a thermal compensated magnet may only require temperature control, for example, of 20 degrees Celsius over a one or two hour period. Thus, the cooling system for the magnet and/or the magnetometer may be passive or much smaller, simpler, lighter, lower power consuming, and cheaper than an active cooling system.

The foregoing description is provided to enable a person skilled in the art to practice the various configurations described herein. While the subject technology has been particularly described with reference to the various figures and configurations, it should be understood that these are for illustration purposes only and should not be taken as limiting the scope of the subject technology. In some aspects, the subject technology may be used in various markets, including for example and without limitation, advanced sensors and mobile space platforms.

There may be many other ways to implement the subject technology. Various functions and elements described herein may be partitioned differently from those shown without departing from the scope of the subject technology. Various modifications to these embodiments may be readily apparent to those skilled in the art, and generic principles defined herein may be applied to other embodiments. Thus, many changes and modifications may be made to the subject technology, by one having ordinary skill in the art, without departing from the scope of the subject technology.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases. Every combination of components described or exemplified can be used to practice the embodiments, unless otherwise stated. Some embodiments can be modified to incorporate any number of variations, alterations, substitutions or equivalent arrangements not heretofore described, but which are commensurate with the spirit and scope of the embodiments. Additionally, while various embodiments of the disclosure have been described, it is to be understood that aspects of the disclosure may include only some of the described embodiments. Accordingly, the disclosure is not to be seen as limited by the foregoing description.

A reference to an element in the singular is not intended to mean “one and only one” unless specifically stated, but rather “one or more.” The term “some” refers to one or more. Underlined and/or italicized headings and subheadings are used for convenience only, do not limit the subject technology, and are not referred to in connection with the interpretation of the description of the subject technology. All structural and functional equivalents to the elements of the various embodiments described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

What is claimed is:

1. A magnetometer for magnetic detection, comprising:
a magneto-optical defect center material comprising at least one magneto-optical defect center that emits an optical signal when excited by an excitation light;
a radio frequency (RF) exciter system configured to provide RF excitation to the magneto-optical defect center material;
an optical excitation system configured to direct the excitation light to the magneto-optical defect center material;
an optical detector configured to receive the optical signal emitted by the magneto-optical defect center material based on the excitation light and the RF excitation; and
a magnetic field generator configured to generate a magnetic field detected at the magneto-optical defect center material, the magnetic field generator including a plurality of permanent magnets arranged in a Halbach array.

2. The magnetometer of claim 1, wherein a first subset of the plurality of permanent magnets is comprised of a first magnetic material and a second subset of the plurality of permanent magnets is comprised of a second magnetic material different from the first magnetic material.

3. The magnetometer according to claim 2, wherein the first magnetic material comprises samarium cobalt and the second magnetic material comprises neodymium.

4. The magnetometer according to claim 2, wherein the first magnetic material has a first temperature coefficient and the second magnetic material has a second temperature coefficient different than the first temperature coefficient.

5. The magnetometer according to claim 2, wherein the first subset of the plurality of permanent magnets is oriented to generate a magnetic field in a first direction, and the second subset of the plurality of permanent magnets is oriented to generate a magnetic field in a second direction opposite to the first direction.

6. The magnetometer according to claim 1, wherein the magnetic field generator further comprises a mounting frame configured to support the plurality of permanent magnets therein.

7. The magnetometer according to claim 6, wherein the mounting frame comprises a plurality of mounting holes extending along sides thereof, and each mounting hole is configured to receive one or more permanent magnets.

8. The magnetometer according to claim 7, wherein each mounting hole is configured to receive a first permanent magnet having a first length and a second permanent magnet having a second length shorter than the first length.

9. The magnetometer according to claim 7, wherein a first mounting hole of the plurality of mounting holes is configured to receive a permanent magnet comprised of a first magnetic material, and a second mounting hole of the plurality of mounting holes is configured to receive a permanent magnet comprised of a second magnetic material different from the first magnetic material.

10. The magnetometer according to claim 6, wherein the mounting frame is circular and includes a plurality of recesses along a circumference thereof, each recess configured to receive one of the permanent magnets.

11. The magnetometer according to claim 10, wherein at least one of the permanent magnets is comprised of a first magnetic material and at least one of the permanent magnets is comprised of a second magnetic material different from the first magnetic material.

12. The magnetometer according to claim 11, wherein the at least one of the permanent magnets comprised of the first magnetic material is larger in size than the at least one of the permanent magnets comprised of the second magnetic material.

13. The magnetometer according to claim 9, wherein the first magnetic material comprises samarium cobalt and the second magnetic material comprises neodymium.

14. The magnetometer according to claim 6, wherein the magneto-optical defect center material and the magnetic field generator are mounted to a base, and the magneto-optical defect center material is provided at a center of the mounting frame.

15. The magnetometer according to claim 6, wherein the magneto-optical defect center material and the magnetic field generator are mounted to a base, and the magneto-optical defect center material is provided offset from a center of the mounting frame.

16. The magnetometer according to claim 14, wherein the mounting frame includes one or more alignment and mounting holes along a periphery thereof, and the mounting frame is mounted to the base via one or more fasteners configured to be received in the one or more alignment and mounting holes.

17. The magnetometer according to claim 15, wherein the mounting frame includes one or more alignment and mounting holes along a periphery thereof, and the mounting frame is mounted to the base via one or more fasteners configured to be received in the one or more alignment and mounting holes.

18. The magnetometer according to claim 14, wherein the mounting frame is configured to be repeatedly and reversibly mounted to the base in a plurality of different orientations to change the magnetic field detected at the magneto-optical defect center material.

19. The magnetometer according to claim 1, further comprising at least one thermistor configured to be affixed to one of the permanent magnets and configured to monitor a temperature of the one of the permanent magnets.

20. The magnetometer according to claim 1, wherein the magneto-optical defect center material comprises a nitrogen vacancy (NV) diamond material comprising at least one NV center.

21. The magnetometer according to claim 1, wherein the magneto-optical defect center material comprises a nitrogen vacancy (NV) diamond material comprising a plurality of NV centers.

22. A magnetic field generator comprising:
a plurality of permanent magnets arranged in a Halbach array,
wherein a first subset of the plurality of permanent magnets is comprised of a first magnetic material, and
wherein a second subset of the plurality of permanent magnets is comprised of a second magnetic material different from the first magnetic material.

23. The magnetic field generator according to claim 22, wherein the first magnetic material comprises samarium cobalt and the second magnetic material comprises neodymium.

24. The magnetic field generator according to claim 23, wherein the first magnetic material has a first temperature coefficient and the second magnetic material has a second temperature coefficient different than the first temperature coefficient.

25. The magnetic field generator according to claim 23, wherein the first subset of the plurality of permanent magnets is oriented to generate a magnetic field in a first direction, and the second subset of the plurality of permanent magnets is oriented to generate a magnetic field in a second direction opposite to the first direction.

26. The magnetic field generator according to claim 22, further comprising a mounting frame configured to support the plurality of permanent magnets therein.

27. The magnetic field generator according to claim 26, wherein the mounting frame comprises a plurality of mounting holes extending along sides thereof, and each mounting hole is configured to receive one or more permanent magnets.

28. The magnetic field generator according to claim 27, wherein each mounting hole is configured to receive a first permanent magnet having a first length and a second permanent magnet having a second length shorter than the first length.

29. The magnetic field generator according to claim 27, wherein a first mounting hole of the plurality of mounting holes is configured to receive a permanent magnet comprised of a first magnetic material, and a second mounting hole of the plurality of mounting holes is configured to receive a permanent magnet comprised of a second magnetic material different from the first magnetic material.

30. The magnetic field generator according to claim 26, wherein the mounting frame is circular and includes a plurality of recesses along a circumference thereof, each recess configured to receive one of the permanent magnets.

31. The magnetic field generator according to claim 30, wherein at least one of the permanent magnets is comprised of a first magnetic material and at least one of the permanent magnets is comprised of a second magnetic material different from the first magnetic material.

32. The magnetic field generator according to claim 31, wherein the at least one of the permanent magnets comprised of the first magnetic material is larger in size than the at least one of the permanent magnets comprised of the second magnetic material.

33. The magnetic field generator according to claim 29, wherein the first magnetic material comprises samarium cobalt and the second magnetic material comprises neodymium.

34. The magnetic field generator according to claim 26, wherein the mounting frame includes one or more alignment and mounting holes along a periphery thereof, and the mounting frame is mounted to the base via one or more fasteners configured to be received in the one or more alignment and mounting holes.

35. The magnetic field generator according to claim 26, wherein the mounting frame is configured to be repeatedly and reversibly mounted to the base in a plurality of different orientations to change the magnetic field detected at the magneto-optical defect center material.

36. The magnetic field generator according to claim 22, further comprising at least one thermistor configured to be affixed to one of the permanent magnets and configured to monitor a temperature of the one of the permanent magnets.

37. A magnetometer for magnetic detection, comprising:
a magneto-optical defect center material comprising at least one magneto-optical defect center that emits an optical signal when excited by an excitation light;
radio frequency (RF) excitation means for providing RF excitation to the magneto-optical defect center material;
optical excitation means for directing the excitation light to the magneto-optical defect center material;
optical detection means for detecting the optical signal emitted by the magneto-optical defect center material based on the excitation light and the RF excitation; and
magnetic field generation means for generating a magnetic field detected at the magneto-optical defect center material, the magnetic field generation means including a plurality of permanent magnets arranged in a Halbach array.

38. The magnetometer of claim 37, wherein a first subset of the plurality of permanent magnets is comprised of a first magnetic material and a second subset of the plurality of permanent magnets is comprised of a second magnetic material different from the first magnetic material.

39. The magnetometer according to claim 38, wherein the first magnetic material comprises samarium cobalt and the second magnetic material comprises neodymium.

40. The magnetometer according to claim 38, wherein the first magnetic material has a first temperature coefficient and the second magnetic material has a second temperature coefficient different than the first temperature coefficient.

41. The magnetometer according to claim 38, wherein the first subset of the plurality of permanent magnets is oriented to generate a magnetic field in a first direction, and the second subset of the plurality of permanent magnets is oriented to generate a magnetic field in a second direction opposite to the first direction.

42. The magnetometer according to claim 37, wherein the magnetic field generation means further comprises a mounting means for supporting the plurality of permanent magnets therein.

43. The magnetometer according to claim 42, wherein the mounting means comprises a plurality of mounting holes extending along sides thereof, and each mounting hole is configured to receive one or more permanent magnets.

44. The magnetometer according to claim 43, wherein each mounting hole is configured to receive a first permanent magnet having a first length and a second permanent magnet having a second length shorter than the first length.

45. The magnetometer according to claim 43, wherein a first mounting hole of the plurality of mounting holes is configured to receive a permanent magnet comprised of a first magnetic material, and a second mounting hole of the plurality of mounting holes is configured to receive a permanent magnet comprised of a second magnetic material different from the first magnetic material.

46. The magnetometer according to claim 42, wherein the mounting means is circular and includes a plurality of recesses along a circumference thereof, each recess configured to receive one of the permanent magnets.

47. The magnetometer according to claim 46, wherein at least one of the permanent magnets is comprised of a first magnetic material and at least one of the permanent magnets is comprised of a second magnetic material different from the first magnetic material.

48. The magnetometer according to claim 47, wherein the at least one of the permanent magnets comprised of the first magnetic material is larger in size than the at least one of the permanent magnets comprised of the second magnetic material.

49. The magnetometer according to claim 45, wherein the first magnetic material comprises samarium cobalt and the second magnetic material comprises neodymium.

50. The magnetometer according to claim 42, wherein the magneto-optical defect center material and the magnetic field generation means are mounted to a base, and the magneto-optical defect center material is provided at a center of the mounting means.

51. The magnetometer according to claim 42, wherein the magneto-optical defect center material and the magnetic field generation means are mounted to a base, and the magneto-optical defect center material is provided offset from a center of the mounting means.

52. The magnetometer according to claim 50, wherein the mounting means includes one or more alignment and mounting holes along a periphery thereof, and the mounting means is mounted to the base via one or more fastening means received in the one or more alignment and mounting holes.

53. The magnetometer according to claim 51, wherein the mounting means includes one or more alignment and mounting holes along a periphery thereof, and the mounting means is mounted to the base via one or more fastening means received in the one or more alignment and mounting holes.

54. The magnetometer according to claim 50, wherein the mounting means is configured to be repeatedly and reversibly mounted to the base in a plurality of different orientations to change the magnetic field detected at the magneto-optical defect center material.

55. The magnetometer according to claim 37, further comprising at least one temperature measuring means for measuring a temperature of the one or more permanent magnets, the temperature measuring means being affixed to one of the permanent magnets.
